(19) United States
(12) Patent Application Publication
(10) Pub. No.: US 2008/0150062 A1
(43) Pub. Date: Jun. 26, 2008

(54) Image sensor fabricating method

(75) Inventor: Joon Hwang, Cheongju-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 12/002,191

(22) Filed: Dec. 13, 2007

(30) Foreign Application Priority Data
Dec. 21, 2006 (KR) 10-2006-0131529

(51) Int. Cl. H01L 31/0232

(52) U.S. Cl. 257/432; 438/70; 257/E31.127

(57) ABSTRACT

An image sensor fabricating method includes forming a photoresist layer on a color filter layer, exposing the photoresist layer to form a pattern having a predetermined depth from a top surface of the photoresist layer, heat-treating the photoresist layer to form microlens precursors, and etching the microlens precursors to form microlenses.

The present application claims priority under 35 U.S.C. 119 and 35 U.S.C. 365 to Korean Patent Application No. 10-2006-0131529 (filed on Dec. 21, 2006), which is hereby incorporated by reference in its entirety.

### BACKGROUND

Embodiments of the invention relate to an image sensor fabricating method.

Generally, an image sensor is a semiconductor device that converts optical images into electric signals. The image sensor includes a microlens for condensing incident light onto a photodiode.

FIGS. 1 and 2 are cross-sectional views of a related art image sensor fabricating method.

According to the related art image sensor fabricating method, photoresist patterns 11 are formed in a matrix as illustrated in FIG. 1. Referring to FIG. 2, a thermal treatment process, e.g., a reflow process, is performed on the photoresist patterns 11 to form microlenses 11a.

The microlenses 11a can be formed in a matrix through the above-mentioned processes. In this case, the microlenses 11a adjacent to each other in a horizontal direction have a predetermined gap “s” between them. The microlenses 11a adjacent to each other in a vertical direction also have the predetermined gap “s” between them.

Due to the limitation in resolution of an exposing apparatus, adjacent photoresist patterns 11 are formed spaced apart from one another by 0.3-0.5 μm. The adjacent microlenses 11a formed by the thermal treatment process are spaced apart from one another by 0.2-0.4 μm.

One important issue in fabricating the image sensor is to increase the sensitivity of the image sensor, i.e., the conversion rate of an incident light signal to an electric signal. In fabricating a high-integrated image sensor, there is a demand for microlenses having a zero gap so as to effectively induce and/or increase the incident light to photodiodes due to reduction of pixel pitch.

In forming the microlenses for condensing the incident light, various attempts have been made to provide a zero gap between the microlenses. The zero gap indicates that no gap is formed between the adjacent microlenses. However, limitations in the resolution of an exposing apparatus (e.g., a photolithographic stepper) make it difficult to form a zero gap between the adjacent microlenses.

### SUMMARY

Embodiments of the invention provide an image sensor fabricating method that can provide a zero gap between adjacent microlenses, thereby improving sensitivity of the image sensor.

An embodiment provides an image sensor fabricating method including: forming a photoresist layer on a color filter layer; exposing the photoresist layer to form a pattern in the photoresist layer having a predetermined depth from a top surface of the photoresist layer; heating the photoresist layer to form microlens precursors; and etching the microlens precursors to form microlenses.

Another embodiment provides an image sensor fabricating method including: forming a planarization layer on a color filter layer; forming a photoresist layer on the planarization layer; exposing the photoresist layer to form a pattern in the photoresist layer; heating the photoresist layer to form microlens precursors; and etching the microlens precursors to form microlenses.

### BRIEF DESCRIPTION OF THE DRAWINGS

FIGS. 1 and 2 are cross-sectional views of a related art image sensor fabricating method.

FIGS. 3 to 6 are conceptual views of an image sensor fabricating method according to exemplary embodiments of the invention.

FIG. 7 is a cross-sectional view of an image sensor according to other exemplary embodiments.

### DETAILED DESCRIPTION OF THE EMBODIMENTS

In the description of embodiments, when each layer, regions, patterns, or structures are referred to as being “on/above” or “under/below”, it can be construed that they can be directly on the other layer or structures, or intervening layers, patterns, structures may also be present. Therefore, the meaning thereof should be determined according to the spirit of the embodiments and/or the context of the disclosure.

Hereinafter, exemplary embodiments will be described in detail with reference to the accompanying drawings.

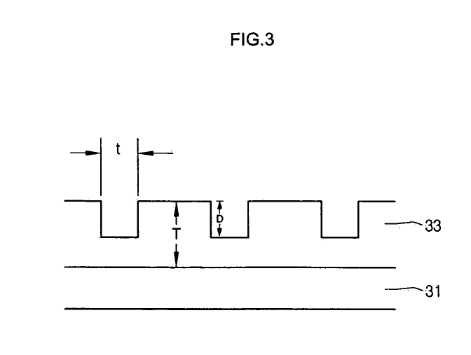

FIGS. 3 to 6 are conceptual views of an image sensor fabricating method according to certain embodiments of the invention.

Referring to FIGS. 3 to 6, a photoresist layer 33 for formation of microlenses is formed on a color filter layer 31. The image sensor fabricating method may further include forming a light receiving portion on a semiconductor substrate before forming the color filter layer 31. A photodiode may be used as the light receiving portion. Also, the color filter layer 31 may comprise a blue color filter (B), a green color filter (G), and a red color filter (R). Alternatively, the color filters may comprise a yellow color filter (Y), a cyan color filter (C), and a magenta color filter (M). Generally, each color filter is separately formed by deposition and photolithographic patterning (e.g., exposure and development). Subsequently, an exposure process is performed to form a pattern in the photoresist layer 33 having a predetermined depth from the top surface of the photoresist layer 33. Such irradiation is generally performed for a length of time correlated to a target penetration in the photoresist layer 33 (e.g., to a particular depth) as a function of time. In the photoresist layer 33, adjacent patterns (which may be the unetched parts remaining after forming a plurality of orthogonal trenches in the photoresist layer 33 by development of the exposed photoresist 33) may be spaced apart from one another by a gap “t” of 0.1-0.2 μm. In some cases, the gap “t” may be as small as the photolithography equipment can form (e.g., 90, 65, 45, or 32 nm).

The exposure process is performed until development of the photoresist layer 33 patterns the photoresist layer 33 to the predetermined depth, but not to a depth equal to a thickness of the photoresist layer 33. For example, as shown in FIG. 3, the depth D of the trench is less than the thickness T of the photoresist layer 33. In general, the ratio D/T depends on the target height and curvature of the microlenses, but in various embodiments, the ratio D/T may be from about 1:10 to about 10:1, about 1:5 to about 5:1, or about 1:3 to about 3:1. By performing the exposure process, the resolution of the exposing apparatus can be used to form the patterns having a relatively narrow gap.

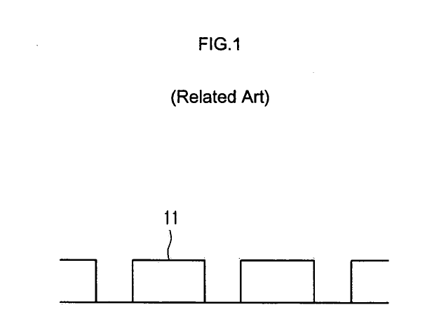

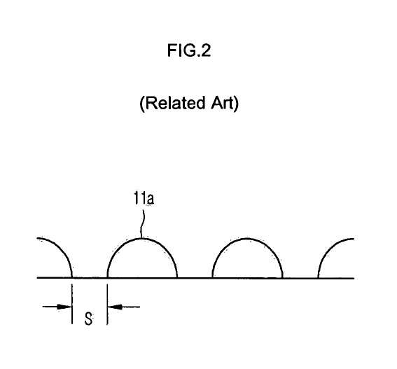

For example, when a related art exposure process is used, as described above with reference to FIGS. 1 and 2, the patterns have a gap ranging from 0.3 μm to 0.5 μm due to the limitation of the resolution of the exposing apparatus and the required depth of irradiation. However, according to the embodiment of the invention shown in FIG. 3, the photoresist layer 33 patterned to the predetermined depth may be formed such that the adjacent patterns are spaced apart from one another by the gap “t” of 0.1-0.2 μm.

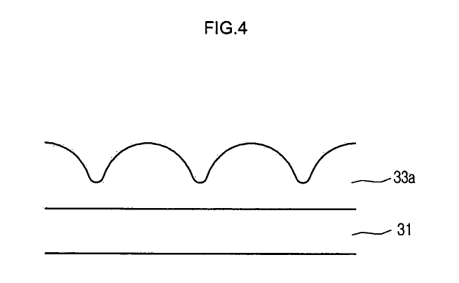

Referring to FIG. 4, the photoresist layer 33 is heated to form microlens precursors 33a. Such heating may be at a temperature sufficient to reflow the photoresist material in the photoresist layer 33 (e.g., from about 120° C. to about 250° C., particularly from about 150° C. to about 200° C.).

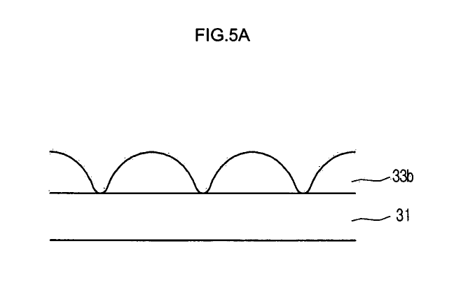

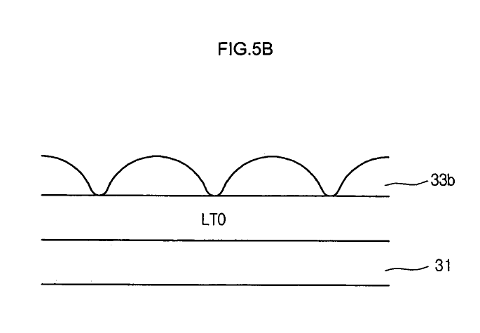

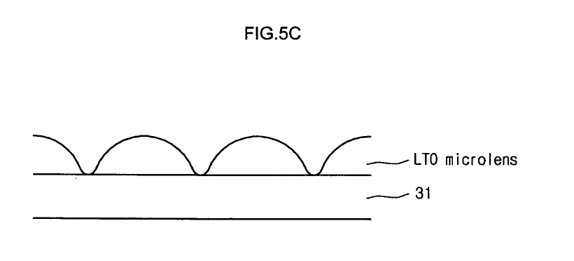

Referring to FIG. 5A, the microlens precursors 33a are etched to form microlenses 33b. The etching process on the microlens precursors 33a may be a blanket etching process (e.g., anisotropic etching or an etch back process).

The microlenses 33b can thus be gapless. That is, no gap is formed between the adjacent microlenses. Hence, the amount of light received into the light receiving portion (e.g., a photodiode) is increased by condensing more incident light, thereby enhancing sensitivity of the image sensor.

FIG. 5B shows an embodiment where the microlenses are formed on a low temperature oxide (LTO; suitable materials for which are described elsewhere herein). In one embodiment, the LTO layer can serve as a planarization layer (generally following chemical mechanical polishing of the LTO layer as deposited onto color filter layer 31).

Alternatively, and as shown in FIG. 5C, when the anisotropic etch (or etch back) for forming the microlenses is not very selective for the resist material of the microlens as compared to the LTO (e.g., an etch selectivity ratio of about 1:1), one may continue the etch or etch back into the LTO layer to form LTO-based microlenses. In such an embodiment, the LTO layer may have a thickness at least the same as (and preferably greater than) the thickness of the resist layer 33 for the microlenses, to enable complete removal of the resist layer 33 and enable formation of gapless LTO microlenses.

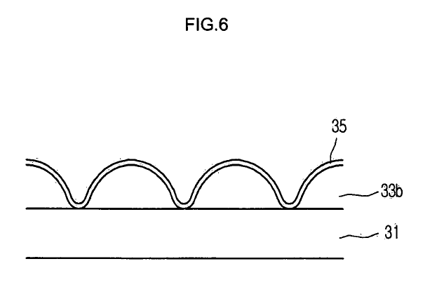

According to another embodiment of the image sensor fabricating method, as illustrated in FIG. 6, a low temperature oxide (LTO) layer 35 may be further formed on the microlenses 33b after the formation of the microlenses 33b. The LTO layer 35 prevents the microlenses 33b from being scratched or damaged by external particles.

Although the microlenses formed on the color filter layer 31 have been described, the image sensor fabricating method is not limited thereto. In an alternative embodiment, a planarization layer can be formed on the color filter layer 31, and the microlenses 33b can then be formed on the planarization layer.

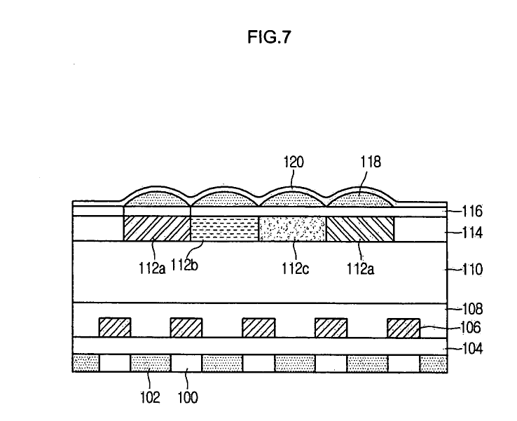

FIG. 7 is a cross-sectional view of an image sensor according to an embodiment, illustrating principal parts of the image sensor related to condensation.

Referring to FIG. 7, the image sensor according to an embodiment includes one or more light receiving portions 102 (e.g., photodiodes), one or more field insulators 100 (e.g., shallow trench isolation structures), interlayer insulating layers 104 and 108, and light shield layers 106 (each of which may also serve as a metallization layer for transferring signals into and out from a unit pixel including a photodiode 102, as well as within the unit pixel). The light receiving portions 102 and the field insulators 100 are formed on a semiconductor substrate. The interlayer insulating layers 104 and 108 are disposed above the receiving portions 120 and the field insulators 100. The light shield layers 106 are formed in the interlayer insulating layer 108 and/or on insulating layer 104 and prevent some or all light from being incident into other regions except the light receiving portion directly under a given microlens 118 and corresponding color filter 112a, 112b, 112c, or 112d.

A passivation layer 110 is formed on the interlayer insulating layer 108. Red, green and blue color filters 112a, 112b and 112c are sequentially formed in an array on the passivation layer 110. In various embodiments, a first color filter (e.g., the blue color filter) may have a height of from 6000 to 7500 [symbol] (for example, from 6500 to 7200 [symbol] ), a second color filter (e.g., the green color filter) may have a height greater than that of the first color filter, in the range of from 6500 to 8000 [symbol] (for example, from 7000 to 7500 [symbol] ), and a third color filter 93 (e.g., the red color filter) may have a height greater than that of the second color filter, in the range of from 7000 to 9000 [symbol] (for example, from 7500 to 8500 [symbol] ).

Thus, a planarization layer 116 may be formed on the color filters 112a, 112b and 112c to provide a smooth, planar surface on which to form the microlenses. Microlenses 118 having a convex lens shape are disposed at positions opposite to the color filters 112a, 112b and 112c, respectively. An LTO layer 120 is formed on the microlenses 118. LTO layer 120 may comprise a TEOS-based oxide or a plasma silane-based oxide. Thus, LTO layer 120 may be formed by chemical vapor deposition of a silicon oxide from TEOS and an oxidizing agent (such as dioxygen and/or ozone) or by plasma-assisted deposition of silicon dioxide from silane (SiH₄) and an oxidizing agent (such as dioxygen). The microlenses 118 are formed such that no gap is formed between the adjacent microlenses. A reference numeral “114” denotes a further insulating layer, generally in peripheral regions of the image sensor or regions other than a pixel region.

Incident light is condensed through the microlenses 118. The red color filter 112a, the green color filter 112b, and the blue color filter 112c transmit red light, green light, and blue light, respectively. The filtered light is incident onto the light receiving portion 102 such as a photodiode disposed under each of the color filters 112a, 112b and 112c through the passivation layer 110 and the interlayer insulating layers 108 and 104. The light shield layers 106 serve to prevent the incident light from deviating from its intended path.

According to an embodiment of the image sensor fabricating method, the gapless microlenses can be fabricated, thereby enhancing sensitivity of the image sensor.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor fabricating method comprising:
forming a photoresist layer on a color filter layer;
exposing the photoresist layer to form a pattern in the photoresist layer having a predetermined depth;
heating the photoresist layer to form microlens precursors; and
etching the microlens precursors to form microlenses.

2. The image sensor fabricating method according to claim 1, wherein the pattern comprises a plurality of raised portions surrounded by a plurality of orthogonal trenches in the photoresist layer, the raised portions being spaced apart from one other by 0.1-0.2 μm.

3. The image sensor fabricating method according to claim 1, further comprising forming a light receiving portion in a semiconductor substrate before forming the color filters.

4. The image sensor fabricating method according to claim 3, wherein the light receiving portion comprises a photodiode.

5. The image sensor fabricating method according to claim 1, further comprising forming a low temperature oxide (LTO) on the microlenses.

6. The image sensor fabricating method according to claim 1, wherein the adjacent microlenses are gapless.

7. The image sensor fabricating method according to claim 6, wherein etching the microlens precursors comprises a blanket etching process.

8. The image sensor fabricating method according to claim 1, wherein the depth of the pattern is less than a thickness of the photoresist layer.

9. The image sensor fabricating method according to claim 1, wherein the photoresist layer is formed on a low temperature oxide layer, etching the microlens precursors is performed by blanket etching, and the method further comprises blanket etching the low temperature oxide layer to form low temperature oxide-based microlenses.

10. An image sensor fabricating method comprising:
forming a planarization layer on a color filter layer;
forming a photoresist layer on the planarization layer;
exposing the photoresist layer to form a pattern in the photoresist layer having a predetermined depth;
heating the photoresist layer to form microlens precursors; and
etching the microlens precursors to form microlenses.

11. The image sensor fabricating method according to claim 10, wherein the pattern comprises a plurality of raised portions surrounded by a plurality of orthogonal trenches, the raised portions being spaced apart from one another by 0.1-0.2 μm.

12. The image sensor fabricating method according to claim 10, further comprising forming a light receiving portion on a semiconductor substrate before forming the color filters.

13. The image sensor fabricating method according to claim 12, wherein the light receiving portion comprises a photodiode.

14. The image sensor fabricating method according to claim 10, further comprising forming a low temperature oxide (LTO) on the microlenses.

15. The image sensor fabricating method according to claim 10, wherein adjacent microlenses are gapless.

16. The image sensor fabricating method according to claim 10, wherein etching the microlens precursors comprises a blanket etching process.

17. The image sensor fabricating method according to claim 10, wherein the depth of the pattern is less than a thickness of the photoresist layer.

18. The image sensor fabricating method according to claim 10, wherein the photoresist layer is formed on a low temperature oxide layer, etching the microlens precursors is performed by blanket etching, and the method further comprises blanket etching the low temperature oxide layer to form low temperature oxide-based microlenses.

19. An image sensor comprising:
a semiconductor substrate with a plurality of light receiving portions thereon;
an insulating layer on or over the light receiving portions;
a color filter layer on or over the insulating layer; and
microlenses on the color filter layer, wherein adjacent microlenses have a zero gap therebetween.

20. The image sensor according to claim 19, wherein the microlenses comprise a resist.

21. The image sensor according to claim 20, wherein the resist has a generally convex shape, and the microlenses further comprise a low temperature oxide layer on the convex resist.

22. The image sensor according to claim 19, wherein the microlenses comprise a low temperature oxide.
